(19) United States
(12) Patent Application Publication
(10) Pub. No.: US 2011/0303260 A1
(43) Pub. Date: Dec. 15, 2011

(54) SOLAR CELL MODULE AND METHOD OF MANUFACTURING THE SAME

(76) Inventors: Yun-Seok LEE, Seoul (KR); Min-Seok Oh, Gyeonggi-do (KR); Nam-Kyu Song, Gyeonggi-do (KR); Min Park, Seoul (KR); Jung-Tae Kim, Seoul (KR)

(21) Appl. No.: 12/912,692

(22) Filed: Oct. 26, 2010

(30) Foreign Application Priority Data
Jun. 10, 2010 (KR) 2010-0054978

(51) Int. Cl. H01L 31/05; H01L 31/0224

(52) U.S. Cl. 136/244; 438/73; 257/E31.126

(57) ABSTRACT

A solar cell module includes an array substrate, a plurality of solar cells and a between-cell bus electrode. The solar cells are arranged to be adjacent to each other on the array substrate. Each of the solar cells includes a wire electrode. The bus electrode between the cells partially overlaps with each of adjacent solar cells and extends in a first direction, to be electrically connected to the wire electrode of each of the adjacent solar cells. Accordingly, the power efficiency of the solar cell module may be improved.

### CROSS REFERENCE TO RELATED APPLICATION

This application claims priority under 35 U.S.C. §119 to Korean Patent Application No. 2010-54978, filed on Jun. 10, 2010 in the Korean Intellectual Property Office (KIPO), the contents of which are herein incorporated by reference in their entirety.

### BACKGROUND

1. Field of the Invention

Example embodiments of the subject matter disclosed herein relate to a solar cell module and a method of manufacturing the same. More particularly, example embodiments of relate to a solar cell module for improving power efficiency and a method of manufacturing the same.

2. Description of the Related Art

Recently, demand for solar energy has increased. As a result, a solar cell converting the solar energy into an electrical energy has been developed.

The solar cell includes a semiconductor layer converting the solar energy into electrical energy, a transparent electrode layer formed on the semiconductor layer to receive light, and a wire electrode formed on the transparent electrode to output electrons and holes generated in the semiconductor layer into an external device.

The wire electrode includes a body electrode and a finger electrode extended from the body electrode. The wire electrode may be formed by screen printing. However, in forming the wire electrode, the wire electrode may be disconnected due to a surface unevenness of the semiconductor layer, a wire paste viscosity, a stencil defect, etc. Therefore, the body electrode may be disconnected with the finger electrode, or the finger electrode may be opened by itself. An opened finger electrode refers to a poor finger electrode.

The disconnection of the wire electrode prevents the electrons and holes generated in the semiconductor layer from being collected. For example, an amount of current may be decreased due to the disconnection of the wire electrode. Therefore, the power efficiency of the solar cell may be decreased.

### SUMMARY

Example embodiments of the subject matter disclosed herein provide a solar cell module capable of collecting electrons or holes from poor finger electrodes as well as good finger electrodes to improve the power efficiency.

Example embodiments also provide a method of manufacturing the same.

According to one aspect, a solar cell module includes an array substrate, a plurality of solar cells and a between-cell bus electrode. The solar cells are arranged adjacent to each other on the array substrate. Each of the solar cells includes a wire electrode. The bus electrode between the cells partially overlaps with each of adjacent solar cells and extends in a first direction, to be electrically connected to the wire electrode of each of the adjacent solar cells.

In one embodiment, each of the solar cells may include a semiconductor substrate and a transparent electrode. The semiconductor substrate may include first and second surfaces. The first surface may have a first area corresponding to an edge of the semiconductor substrate and a second area except for the first area of the semiconductor substrate. The second surface may be opposite to the first surface having the first and second areas. The transparent electrode may be formed in at least one second area of the first and second surfaces.

In an example embodiment, the semiconductor substrate may include a base substrate, a first semiconductor layer and a second semiconductor layer. The first semiconductor layer may be formed on at least one of the first and second surfaces. The second semiconductor layer may be formed on the first semiconductor layer.

In an example embodiment, the wire electrode may be disposed in the first and second areas.

In an example embodiment, the wire electrode may include a plurality of body electrodes and a plurality of finger electrodes. The body electrodes may extend in the first direction. The finger electrodes may include first and second end portions. The first end portion may be disposed in the second area to be connected to the body electrode, and the second end portion may be disposed in the first area.

In an example embodiment, the solar cell module may further include a bus electrode in the cell extending in the first direction and formed along each of the body electrodes, to be electrically connected to the wire electrode of the solar cell.

In an example embodiment, the wire electrode may further include a sub electrode extending in the first direction in the first area to electrically connect the second end portions of the finger electrodes disposed in the first area.

In an example embodiment, the adjacent solar cells may include first solar cells adjacent to each other in the second direction and second solar cells adjacent to the first solar cells in the first direction. A first end portion of the bus electrode between the cells may extend in the first direction between the first solar cells and may partially overlap with the first surface of each of the first solar cells. A second end portion of the bus electrode between the cells may extend in the first direction between the second solar cells and may partially overlap with the second surface of each of the second solar cells.

In an example embodiment, the adjacent solar cells may include first solar cells adjacent to each other in the second direction and second solar cells adjacent to the first solar cells in the first direction. A first end portion of the bus electrode between the cells may extend in the first direction between the first solar cells and may partially overlap with the first surface of each of the first solar cells. A second end of the bus electrode between the cells may extend in the first direction between the second solar cells and may partially overlap with the first surface of each of the second solar cells.

According to another aspect of the subject matter disclosed herein, there is a method of manufacturing a solar cell module. In the method, a plurality of solar cells having a wire electrode is formed. The solar cells adjacent to each other are arranged on an array substrate. A bus electrode between the cells is formed to partially overlap with each of the adjacent solar cells, and extends in a first direction to be electrically connected to the wire electrode of each of the adjacent solar cells.

In an example embodiment, in the step of forming the solar cells, a semiconductor substrate having a first surface and a second surface opposite to the first surface may be mounted to a shield tray having a through-hole. A transparent electrode in a second area corresponding to the through-hole except for a first area corresponding to an edge of the semiconductor substrate may be deposited on at least one of the first and second surfaces. The wire electrode may be formed on at least one of the first and second surfaces on which the transparent electrode is deposited.

In an example embodiment, in the step of forming the wire electrode, a wire electrode paste may be spread in the first and second areas on the first surface. The wire electrode having a plurality of body electrodes and a plurality of finger electrodes may be screen-printed. The body electrodes extend in the first direction. The finger electrodes have first and second end portions. The first end portion may be disposed in the second area to be connected the body electrodes, and the second end portion may be disposed in the first area.

In an example embodiment, in the method, a bus electrode in the cell may be formed to extend in the first direction and correspond to the body electrodes, to be electrically connected to the wire electrode of the solar cell.

In an example embodiment, in the step of forming the wire electrode, a wire electrode paste may be spread in the first and second areas on the second surface. The wire electrode may be screen-printed.

In an example embodiment, in the step of forming the bus electrode between the cells, a first end portion of the bus electrode between the cells may extend in the first direction between first solar cells adjacent to each other along the second direction. The first end portion may adhere to partially overlap with the first surface of each of the first solar cells adjacent to each other. A second end portion opposite to the first end portion may extend in the first direction between second solar cells adjacent to the first solar cell along the first direction. The second end portion may adhere to partially overlap with the second surface of each of the second solar cells adjacent to each other.

In an example embodiment, in the step of forming the bus electrode between the cells, a first end portion of the bus electrode between the cells may extend in the first direction between first solar cells adjacent to each other along the second direction. The first end portion may adhere to partially overlap with the first surface of each of the first solar cells adjacent to each other. A second end portion opposite to the first end may extend in the first direction between second solar cells adjacent to the first solar cells along the first direction. The second end portion may adhere to partially overlap with the first surface of each of the second solar cells adjacent to each other.

According to the subject matter disclosed herein, the bus electrode between the cells partially overlap with the first area of each of the solar cells adjacent to each other to be electrically connected to at least one of the sub electrode or the finger electrode of each of the solar cells adjacent to each other, thereby collecting the electrons or the holes from the good finger electrode and the poor finger electrode.

Accordingly, the power efficiency of the solar cell module may be improved.

### BRIEF DESCRIPTION OF THE DRAWINGS

The above and other features will become more apparent by describing in detailed example embodiments thereof with reference to the accompanying drawings, in which:

FIG. 1 is a plan view illustrating a solar cell module according to an example embodiment;

FIG. 2A is a cross-sectional view illustrating an example taken along a line I-I′ of FIG. 1;

FIG. 2B is a cross-sectional view illustrating another example taken along the line I-I′ of FIG. 1;

FIG. 3A is a perspective view illustrating an example of a portion ‘A’ of FIG. 1;

FIG. 3B is a perspective view illustrating another example of the portion ‘A’ of FIG. 1;

FIG. 4 is a plan view illustrating a portion ‘B’ of FIG. 1;

FIGS. 5A to 5D are cross-sectional views illustrating a method of manufacturing the solar cell module of FIG. 2B;

FIG. 6 is a plan view illustrating a solar cell module according to another example embodiment;

FIG. 7 is a cross-sectional view taken along a line II-II′ of FIG. 6;

FIG. 8 is a perspective view illustrating a portion ‘E’ of FIG. 1;

FIGS. 9A to 9C are cross-sectional views illustrating a method of manufacturing the solar cell module of FIG. 6;

FIG. 10 is a cross-sectional view illustrating a solar cell module according to still another example embodiment;

FIG. 11 is a perspective view illustrating the solar cell module; and

FIGS. 12A to 12C are cross-sectional views illustrating a method of manufacturing the solar cell module of FIG. 10.

### DETAILED DESCRIPTION

Hereinafter, the subject matter will be explained in detail with reference to the accompanying drawings.

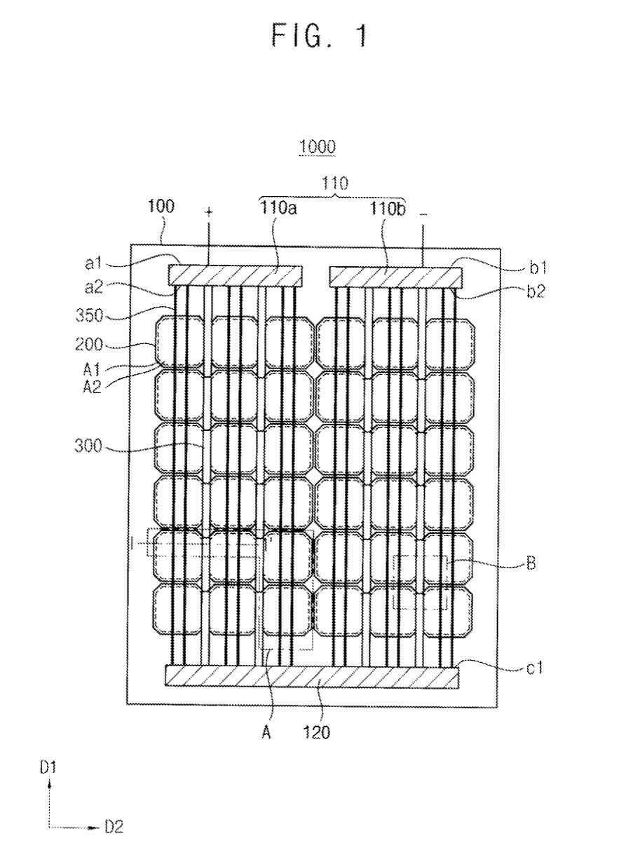

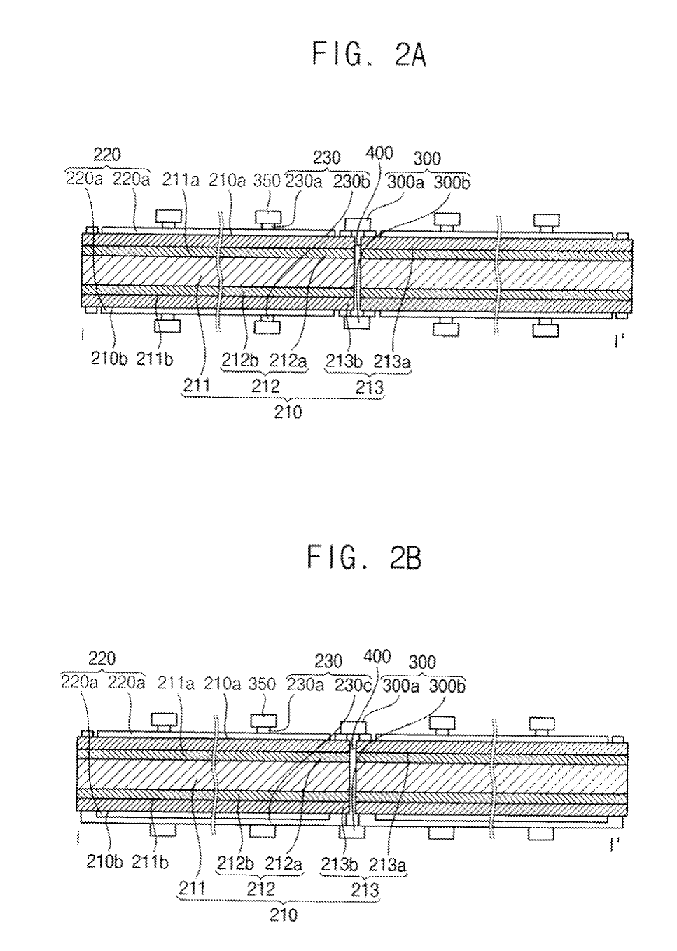

FIG. 1 is a plan view illustrating a solar cell module according to an example embodiment. FIG. 2A is a cross-sectional view illustrating an example taken along I-I′ line of FIG. 1. FIG. 2B is a cross-sectional view illustrating another example taken along I-I′ line of FIG. 1.

Referring to FIGS. 1, 2A and 2B, a solar cell module 1000 according to one embodiment includes an array substrate 100, a solar cell 200 and a bus electrode 300 between the cells 200. The solar cell module 1000 may further include a bus electrode 350 in the cell 200, a first connection electrode 100a and 100b, a second connection electrode 120 and a polyethylene vinyl acetate (EVA) sheet.

A glass substrate or a plastic substrate may be used as the array substrate 100. A surface of the array substrate 100 may be treated for decreasing a loss due to light reflection. The array substrate 100 may include the EVA sheet (not shown).

The solar cell 200 may be arranged in a matrix shape on the array substrate 100. The solar cell 200 may have various shapes such as a rectangular shape, a rectangular shape having a cut-off corner, a circle shape and so on when viewed in a plan.

The solar cell 200 includes a semiconductor substrate 210, a transparent electrode 220 and a wire electrode 230.

The semiconductor substrate 210 includes a base substrate 211, a first semiconductor layer 212 and a second semiconductor layer 213. The semiconductor substrate 210 includes a front surface 210a receiving solar light and a rear surface 210b opposite to the front surface 210a. The semiconductor substrate 210a may have an n-type semiconductor and a p-type semiconductor structure with electrical properties different from each other that are joined together. Thus, the semiconductor substrate 210 may absorb the solar light to generate electrons and holes in the solar cell 200. The holes drift toward the n-type semiconductor and the electrons drift toward the p-type semiconductor, so that the solar cell 200 generates electricity.

The base substrate 211 includes a crystalline semiconductor. The crystalline semiconductor may be one of the n-type and p-type semiconductors. The base substrate 211 includes a front surface 211a receiving the solar light and a rear surface 211b opposite to the front surface 211a. The base substrate 211 may include an uneven surface (not shown). The uneven surface may increase a receiving rate of the solar light.

The first semiconductor layer 212 includes an amorphous semiconductor. The amorphous semiconductor is an i-type (intrinsic type). The first semiconductor layer 212 is disposed on at least one of the front surface 211a and the rear surface 211b of the base substrate 211. For example, the first semiconductor layer 212 may include a first front semiconductor layer 212a disposed on the front surface 211a and a first rear semiconductor layer 212b disposed on the rear surface 211b. The first semiconductor layer 212 has a layer property better than the p-type and n-type semiconductors. Thus, the first semiconductor layer 212 may be disposed between the p-type and n-type semiconductors to increase the receiving rate of the solar light.

The second semiconductor layer 213 includes an amorphous semiconductor. The amorphous semiconductor may be one of the n-type and p-type semiconductors. The second semiconductor layer 213 is disposed on at least one of the first front semiconductor layer 212a and the first rear semiconductor layer 212b. For example, the second semiconductor layer 213 may include a second front semiconductor layer 213a disposed on the first front semiconductor layer 212a and a second rear semiconductor layer 213b disposed on the second rear semiconductor 212b.

For example, when the base substrate 211 has the n-type semiconductor, the second front semiconductor layer 213a may have the p-type semiconductor and the second rear semiconductor layer 213b may have an (n+)-type semiconductor. Thus, a front side 210a of the semiconductor substrate 210 may have a PIN junction, with the base substrate 211 as a center. The semiconductor substrate 210 may have an electric potential substantially the same as the subtraction of an electric potential of the (n+)-type semiconductor from an electric potential of the p-type semiconductor.

The transparent electrode 220 is disposed on the semiconductor substrate 210. The transparent electrode 220 may be disposed on at least the front surface 210a and the rear surface 210b of the semiconductor substrate 210. For example, the transparent electrode 220 may include a front transparent electrode 220a disposed on the front surface 210a and a rear transparent electrode 220b disposed on the rear surface 210b. The transparent electrode 220 may include one of transparent conductive oxides (TCO) such as tin oxide (SnO₂), zinc oxide (ZnO), indium tin oxide (ITO) and so on. The front transparent electrode 220a refracts the solar light received from outside and provides the solar light to the rear transparent electrode 220b.

The transparent electrode 220 is partially formed on the semiconductor substrate 210. For example, the transparent electrode 220 may be formed in an area except for an edge of the semiconductor substrate 210. For example, when the semiconductor 210 includes a first area A1 corresponding to the edge and a second area A2 except for the first area A1, the transparent electrode 220 is prevented from being deposited in the first area A1 by a shied tray having a through-hole. Thus, the transparent electrode 220 is prevented from being deposited by the shied tray so that the transparent electrode 220 may be disposed only in the second area A2. A width of the first area A1 may be less than or equal to about 1 mm.

The wire electrode 230 is disposed on the transparent electrode 220.

The solar cell 200 typically includes a semiconductor 210 having a PN junction. When the solar light is incident on to the front surface 210a of the semiconductor substrate 210, electricity is generated in the semiconductor substrate 210. For example, the electrons and the holes are separated by the potential generated of the PN junction. The electrons drift into the n-type semiconductor and the holes drift into the p-type semiconductor. The drifted electrons and holes output into an external device through the wire electrode 230 to generate an electric current.

The bus electrode between the cells 300 extends in the first direction D1 between the solar cells 200 to partially overlap with the solar cells 200. The bus electrode between the cells 300 is disposed between front surfaces and rear surfaces of solar cells 200 in order to connect the solar cells 200 in series or in parallel. The bus electrode between the cells 300 includes a front surface bus electrode between the cells 300a disposed between the front surfaces of two solar cells 200 adjacent to each other and a rear surface bus electrode between the cells 300b disposed between the rear surfaces of two solar cells 200 adjacent to each other. An EVA sheet 400 fills a gap between the front surface bus electrode between the cells 300a and the rear surface bus electrode between the cells 300b. The bus electrode between the cells 300 outputs the electrons and the holes collected by the wire electrode 230 of each of the solar cells 200 into the external device.

The bus electrode in the cell 350 extends in the first direction D1 along a body electrode (not shown) of the wire electrode 230 in the solar cell 200. The bus electrode in the cell 350 outputs the electrons and the holes collected by the wire electrode 230 of the solar cell 200.

The first connection electrodes 110a and 110b are disposed at an upper side of the array substrate 100 to be connected to the bus electrode between the cells 300 and the bus electrode in the cell 350 which connect the solar cells 200 adjacent to each other in the first direction D1 into the first direction D1. In the solar cell module 1000 according to the present example embodiment, three solar cells 200 adjacent to each other in the second direction D2 are connected to another three solar cells 200 adjacent to the three solar cells 200 in the first direction D1 in series or in parallel. For example, a first end portion a1 of the first connection electrode 110a is connected to a positive (+) terminal of the external device. A second end portion a2 of the first connection electrode 110a is connected the bus electrode between the cells 300 and the bus electrode in the cell 350 connected to the three solar cells 200 adjacent to each other in the second direction D2. A first end portion b1 of the first connection electrode 110b is connected to a negative (−) terminal of the external device. A second end portion b2 of the first connection electrode 110b is connected to the bus electrode between the cells 300 and the bus electrode in the cell 350 connected to another three solar cells 200 adjacent to the three solar cells 200 in the second direction D2.

The second connection electrode 120 is disposed at a lower side of the array substrate 100 to be connected to the bus electrode between the cells 300 and the bus electrode in the cell 350 connecting the solar cells 200 adjacent to each other in the first direction D1. A first end portion cl of the second connection electrode 120 is connected to the cell-bus electrode and the bus electrode in the cell 350 connected to six solar cells 200 adjacent to each other in the second direction D2.

Therefore, the first and second connection electrodes 110a, 110b and 120 may connect the solar cells 200 to the positive (+) and negative (−) terminals of the external device in series or in parallel.

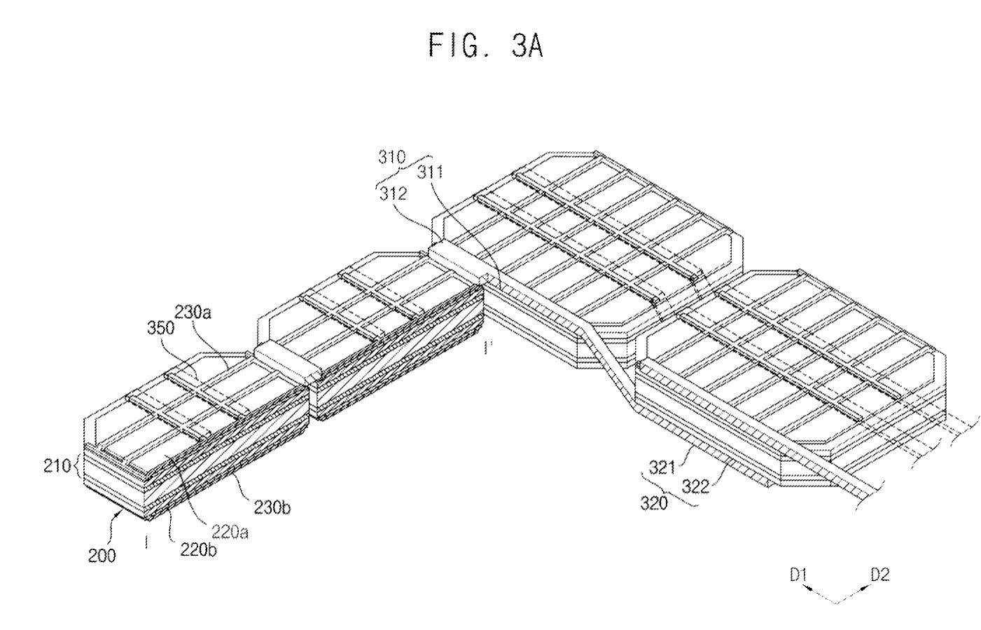

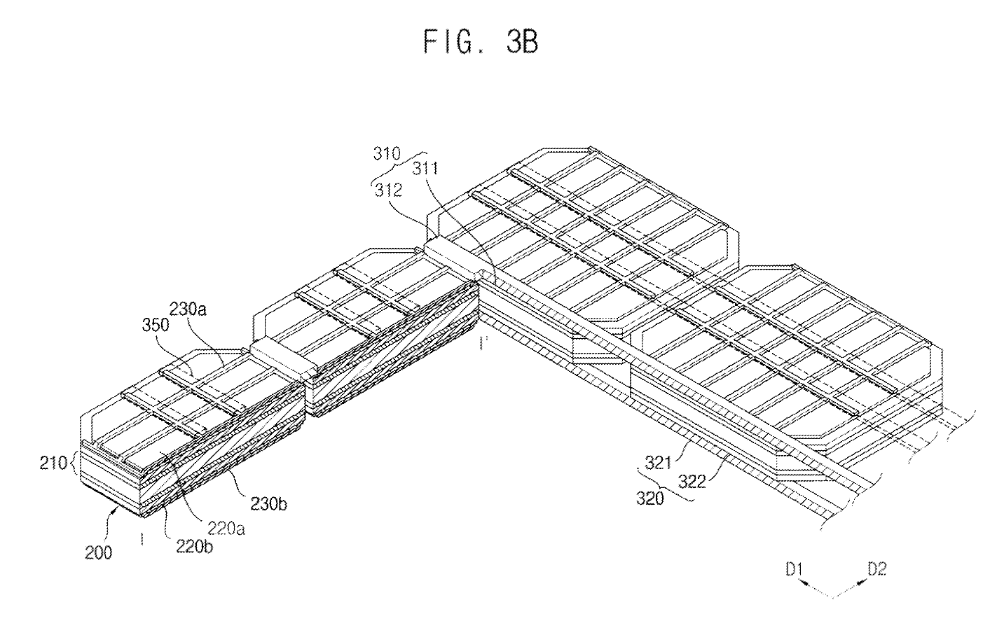

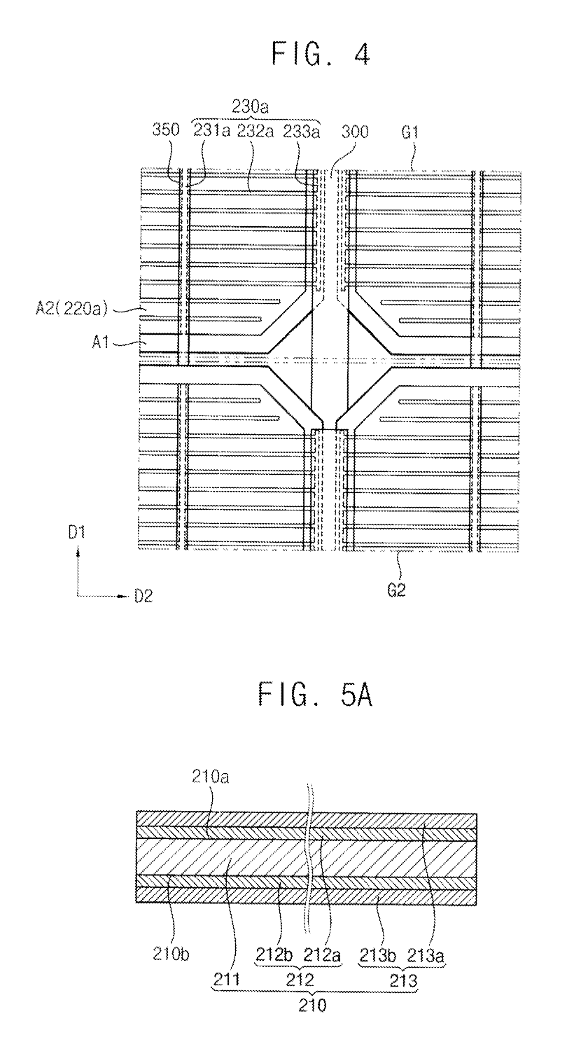

FIG. 3A is a perspective view illustrating an example of ‘A’ of FIG. 1. FIG. 3B is a perspective view illustrating another example of ‘A’ of FIG. 1. FIG. 4 is a plan view illustrating ‘B’ of FIG. 1.

Referring to FIG. 2A to FIG. 4, the solar cell 200 includes the semiconductor substrate 210 having a first area A1 and a second area A2, the transparent electrode 220 disposed in the second area A2 and receiving the solar light, and the wire electrode 230 partially overlapping with the transparent electrode 220 and extended to the first area A1.

The wire electrode 230 is disposed on the semiconductor substrate 210 having the transparent electrode 220 formed on the semiconductor substrate 210. For example, when the transparent electrode 220 is disposed on both of the front surface 210a and the rear surface 210b of the semiconductor substrate 210, the wire electrode 230 may be disposed on both of the front surface 210a and the rear surface 210b of the semiconductor substrate 210. For example, the wire electrode 230 may include a front wire electrode 230a disposed on the front surface 210a and a rear wire electrode 230b disposed on the rear surface 210b. The wire electrode 230 may include one of silver (Ag), aluminum (Al), copper (Cu), nickel (Ni), tungsten (W), titanium (Ti), tin (Sn), nitride tungsten (WN), and metal silicide. The wire electrode 230 may be formed via a screen-printing.

The wire electrode 230 is disposed in the first area A1 and the second area A2 of the semiconductor substrate 210. The wire electrode 230 is uniformly disposed in the second area A2 having the transparent 220. In addition, the wire electrode 230 extends from the second area A2 to the first area A1 to be disposed in both of the first and second areas A1 and A2. For example, the wire electrode 230 is disposed from the second area A2 to a portion of the first area A1, or from the second area A2 to an entire first area A1. The wire electrode 230 partially overlaps with the transparent electrode 210. The wire electrode 230 may have a lattice pattern so as to sufficiently collect the electric current generated from the solar light received to the transparent electrode 210.

The front wire electrode 230a may include the body electrode 231a and the finger electrode 232a. The body electrode 231a extends in a first direction D1. The finger electrode 232a extends from the body electrode 231a. The finger electrode 232a may extend in a second direction D2 crossing the first direction D1. Although not shown in the figure, the finger electrode 232a may extend in a third direction inclined by a certain angle with respect to the first direction D1. In addition, although not shown, the finger electrode 232a may have various shapes including a radial shape.

The front wire electrode 230a may further include a sub electrode 233a. The sub electrode 233a extends along the first direction D1 in the first area A1 of the semiconductor substrate 210 to electrically connect the finger electrodes 232a disposed at an edge of the solar cell 200. The bus electrode between the cells 300 partially overlaps with the first area A1. Therefore, the sub electrode 233a is further disposed in the first area A1, so that a contact area between the sub electrode 233a and the bus electrode between the cells 300 may be increased.

The rear wire electrode 230b may have the same shape as the front wire electrode 230a in order to receive the solar light which is incident into the rear surface of the solar cells 200, as shown in FIG. 2A. Alternately, the rear wire electrode 230b may be entirely formed on the rear surface 211b of the semiconductor substrate 210 without a certain pattern in order to reflect the solar light which is incident into the rear surface of the solar cells 200.

The bus electrode between the cells 300 extends in the first direction D1 between solar cells 200 adjacent to each other in the second direction D2. In the present example embodiment, the bus electrode between the cells is formed between the solar cells adjacent to each other in the second direction D2. Alternatively, the bus electrode between the cells may be formed between the solar cells adjacent to each other in the first direction D1. In this case, the wire electrode may extend in the second direction D2, and the first and second connection electrodes 110a, 110b and 120 may be disposed in left and right sides of the array substrate 100.

The bus electrode between the cells 300 partially overlaps with the first area A1 of each of the solar cells 200. The bus electrode between the cells 300 is electrically connected to the wire electrode 230 disposed in the first area A1. For example, the bus electrode between the cells 300 is electrically connected to at least one of the finger electrode 232a and the sub electrode 233a disposed in the first area A1. The bus electrode between the cells 300 is disposed along the sub electrode 233a in order to output the electrons or the holes drifted to the sub electrode 233a through the finger electrode 232a to an external device. Therefore, the bus electrode between the cells 300 may increase an electrical contact area with the sub electrode 233a. The bus electrode between the cells 300 extends along the first direction D1 to be partially disposed in the first area A1. Accordingly, the bus electrode between the cells 300 may capture the electrons or the holes provided from the finger electrode 232a and the sub electrode 233a disposed in each of the solar cells 200 adjacent to each other.

The bus electrode between the cells 300 may include a metal such as aluminum (Al), copper (Cu), etc. The bus electrode between the cells 300 may be connected to the wire electrode 230 by a resin (not shown) including conductive particles.

The bus electrode between the cells 300 may connect first solar cells G1 adjacent to each other in the second direction D2 of the solar cells and second solar cells G2 adjacent to the first solar cells G1 in the first direction D1 of the solar cells in series or in parallel.

In order to connect the first solar cells G1 with the second solar cells G2 in series, as shown in FIG. 2A and FIG. 3A, a first surface 311 of a first end portion 310 of the bus electrode between the cells 300 extends in the first direction D1 between the first solar cells G1 to partially overlap with the front surface of each of the first solar cells G1 adjacent to each other. The first surface 311 of the first end portion 310 of the bus electrode between the cells 300 makes contact with the front wire electrode 230a (for example, positive (+) polarity) disposed in the first area A1. In addition, a second surface 322 of a second end portion 320 of the bus electrode between the cells 300 extends in the first direction D1 between the second solar cells G2 to partially overlap with the rear surface of each of the second solar cells G2 adjacent to each other. The second surface 322 of the second end portion 320 of the bus electrode between the cells 300 makes contact with the rear wire electrode 230b (for example, negative (−) polarity) disposed in the first area A1. Accordingly, the (+) polarity of the first solar cells G1 is connected to the (−) polarity of the second solar cells G2, and the (+) polarity of the second solar cells G2 is connected to the (−) polarity of the third solar cells G3 adjacent in the first direction D1 to the second solar cells G2, so that the first, second and third solar cells G1, G2 and G3 are connected in series.

In order to connect the first solar cells G1 and the second solar cells G2 in parallel, as shown in FIG. 2A and FIG. 3B, the first surface 311 of the first end portion 310 of the bus electrode between the cells 300 extends in the first direction D1 between the first solar cells G1 to partially overlap with the front surface of each of the first solar cells G1 adjacent to each other. The first surface 311 of the first end portion 310 of the bus electrode between the cells 300 makes contact with the front wire electrode 230a (for example, (+) polarity) disposed in the first area A1. In addition, a first surface 321 of a second end portion 320 of the bus electrode between the cells 300 extends in the first direction D1 between the second solar cells G2 to partially overlap with the front surface of each of the second solar cells G2 adjacent to each other. The first surface 321 of the second end portion 320 of the bus electrode between the cells 300 makes contact with the front wire electrode 230a (for example, (+) polarity) disposed in the first area A1. Accordingly, the (+) polarity of the first solar cells G1 is connected to the (+) polarity of the second solar cells G2 and the (−) polarity of the first solar cells G1 is connected to the (−) polarity of the second solar cells G2 as the (+) polarity is connected, so that the first solar cells G1 and the second solar cells G2 are connected in parallel.

The bus electrode between the cells 300 may prevent the finger electrode 232a from being isolated when the finger electrode 232a is opened in a printing process. For example, a first end portion of the finger electrode 232a is formed to be electrically connected to the body electrode 231a. However, when the finger electrode 232a is printed on the transparent electrode 220, the finger electrode 232a is opened due to a surface unevenness of the transparent electrode 200, a viscosity of the wire paste, a defect of the stencil, etc. Therefore, when a portion of the finger electrode 232a is separated from the body electrode 231 a and is electrically disconnected to the body electrode 231a, a first end portion of a separated finger electrode 232a may be electrically disconnected to the bus electrode in the cell 350 disposed on the body electrode 231a. However, the bus electrode between the cells 350 according to the present example embodiment is formed to partially overlap with a second end portion of the finger electrode 232a. Therefore, although a portion of the finger electrode 232a is separated from the body electrode 231a, the bus electrode between the cells 350 partially overlaps with the second end portion of the separated finger electrode 232a. For example, the separated finger electrode 232a is directly connected to the bus electrode between the cells 300.

In addition, the bus electrode between the cells 300 decreases a path for collecting the electrons or the holes, so that an efficiency of the solar cell may be increased. For example, when the first end portion of the finger electrode 232a is electrically connected to the bus electrode between the cells 300 and the second end portion of the finger electrode 232a is electrically connected to the bus electrode in the cell 350, the electrons or the holes collected in the finger electrode may drift into one having a short path of the bus electrode between the cells 300 and the bus electrode in the cell 350. Thus, according to the present example embodiment, the bus electrode between the cells 300 is further formed, so that the path for collecting the electrons or the holes in the wire electrode 230 may be decreased.

In addition, since the bus electrode between the cells 300 is formed in the first area A1 or the portion of the first area A1 of the semiconductor substrate 210, the bus electrode between the cells 300 does not substantially decrease a light-receiving area of the solar cell 100.

At least one bus electrode in the cell 350 may be disposed in the solar cell. The bus electrode in the cell 350 is disposed on the body electrode 231a. For example, the bus electrode in the cell 350 extends in the first direction D1. Thus, the bus electrode in the cell 350 is electrically connected to the body electrode 231a. The bus electrode in the cell 350 may capture the electrons or the holes provided from the finger electrode 232a connected to the body electrode 231a.

The bus electrode in the cell 350 may connect one of the adjacent solar cells with another adjacent to the solar cell 200 in the first direction (D1) in series or in parallel, like the bus electrode between the cells 300.

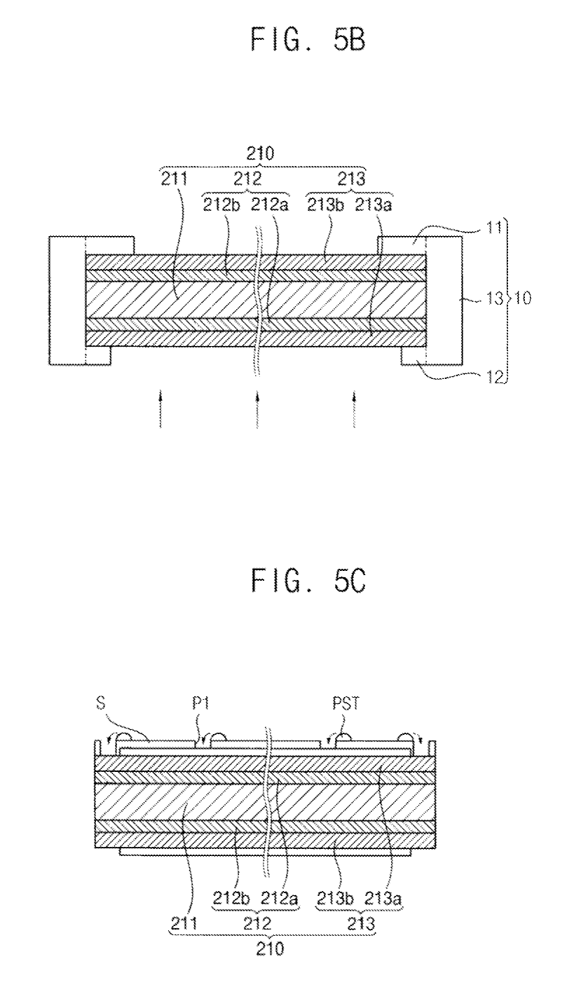

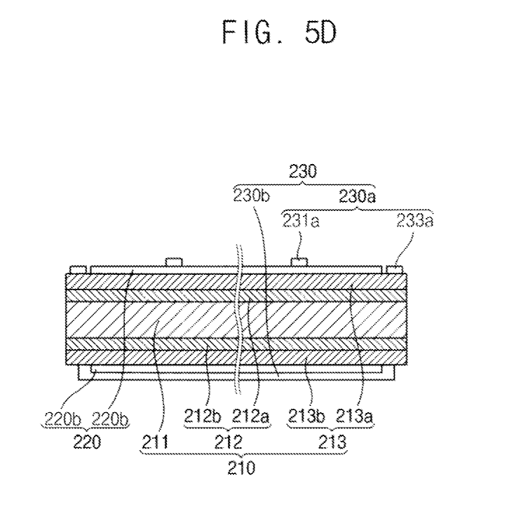

FIGS. 5A to 5D are cross-sectional views illustrating a method of manufacturing the solar cell module of FIG. 2B.

Referring to FIG. 2, FIG. 5A to FIG. 5D, hereinafter, a method of manufacturing the solar cell module 1000 according to the present example embodiment is explained.

Referring to FIG. 2 and FIG. 5A, the base substrate 211 having the n-type semiconductor is textured to be uneven. The front surface 211a of the base substrate 211, or both of the front and rear surfaces 211a and 211b may be uneven.

The first semiconductor layer 212 is deposited on the base substrate 211 having the unevenness. For example, the first front surface semiconductor layer 212a having the i-type semiconductor is deposited on the front surface 211a of the base substrate 211 having the unevenness. The first rear surface semiconductor layer 212b having the i-type semiconductor is deposited on the rear surface 211b of the base substrate 211 having the unevenness.

The second semiconductor layer 213 is deposited on the base substrate 211 having the first semiconductor layer 212 deposited on the base substrate 211. For example, a second front surface semiconductor layer 213a having the p-type semiconductor is deposited on the front surface 211 a of the base substrate 211 having the first semiconductor layer 212 deposited on the base substrate 211. A second rear surface semiconductor layer 213b having the n-type semiconductor is deposited on the rear surface of the base substrate 211 having the first semiconductor layer 212 deposited on the base substrate 211. As described above, the semiconductor substrate 210 having the second semiconductor layer 213 is formed.

Referring to FIG. 2 and FIG. 5B, the semiconductor substrate 210 is mounted on the shield tray 10. An edge of the semiconductor substrate 210 is supported by the shield tray 10. For example, the first area A1 of the semiconductor substrate 210 may be covered by the shield tray 10. Thus, the shield tray 10 prevents the transparent electrode 220 from be deposited in the first area A1 except for the second area A2. The shield tray 10 may have a rectangular shape, a rectangular shape having a cut-off corner, a circle shape or a certain shape corresponding to a circumference of the solar cell in a plan view. A cross-section of the shield tray 10 may have an L-shape or a U-shape.

For example, when the cross-section of the shield tray 10 has the U-shape, the shield tray 10 includes a first side 11, a second side 12 and a third side 13. The first side 11 supports an edge of the front surface 210a of the semiconductor substrate 210, and the second side 12 supports an edge of the rear surface 210b of the semiconductor substrate 210. Alternately, the first side 11 may support the edge of the rear surface 210b of the semiconductor substrate 210, and the second side 12 may support the edge of the front surface 210a of the semiconductor substrate 210. A length of the first side 11 may be longer than that of the second side 12, in order to easily support the semiconductor substrate 210. Thus, when the semiconductor substrate 210 is loaded reversely in a deposition process explained below, the shield tray 10 may support the semiconductor substrate 210 more stably. Alternately, although not shown, the length of the first side 11 is substantially the same as that of the second side 12. For example, the length of the second side 12 may be about 1 mm so that the finger electrode 232a may be sufficiently printed. Alternately, the length of the second side 12 may be less than 1 mm, in order not to decrease the solar light receiving area remarkably. The third side 13 connects the first side 11 with the second side 12.

As shown in FIG. 2 and FIG. 5B, the transparent electrode 220 is deposited on the rear surface 210b of the semiconductor substrate 210. The transparent electrode 220 may be deposited by a chemical vapor deposition (CVD) or a plasma CVD. Alternately, the transparent electrode 220 may be deposited by a sputtering deposition. When the transparent electrode 220 is deposited by the plasma CVD, the semiconductor substrate 210 is loaded reversely. Thus, the transparent electrode 220 is deposited on a lower surface (substantially on the front surface of the semiconductor substrate 210) of the semiconductor 210. The semiconductor substrate 210 may be less damaged through the CVD than through the sputtering deposition.

Referring to FIG. 2 and FIG. 5C, a stencil S having a wire electrode pattern is disposed on the semiconductor substrate 210 having the transparent electrode 220. The stencil S may include the body electrode pattern P1, the finger electrode pattern (not shown) and the sub electrode pattern (not shown). The body electrode pattern P1 and the finger electrode pattern are extended from the second area A2 which is a center of the solar cell 200 to the first area A1 which is an edge of the solar cell 200. The sub electrode pattern is formed in the first area A1 to be connected to the finger electrode pattern formed in the first area A1. A wire electrode material is spread on the stencil S. The wire electrode material may include, for example, silver (Ag) and be in a paste state. Alternately, although not shown, aluminum (Al) paste may be spread on the semiconductor substrate 210 on which the stencil S is disposed.

For example, the wire electrode pattern formed on the front surface 210a of the semiconductor substrate 210 and the wire electrode pattern formed on the rear surface 210b of the semiconductor substrate 210 may be the same or different from each other.

Referring to FIG. 2 and FIG. 5D, the Ag paste disposed in the wire electrode pattern is cured so that the wire electrode 230 is formed. The wire electrode 230 is partially formed on the front surface of the solar cell 200 in order to increase the light-receiving area. However, the wire electrode 230 is entirely formed on the rear surface of the solar cell 200 without patterning, since the rear surface of the solar cell 200 hardly receives the solar light. The rear surface wire electrode 230b reflects the solar light receiving from the front surface of the solar cell 200 to reach the rear surface wire electrode 230b, so that the efficiency of the solar cell 200 may be increased. Accordingly, the solar cell 200 is manufactured.

A plurality of solar cells 200 is arranged in a matrix shape on the array substrate 100 shown in FIG. 1. The bus electrode between the cells 300 extends in the first direction D1 in the first area A1 of each of the solar cells 200 adjacent to each other in the second direction D2 of the arranged solar cells 200. Thus, the bus electrode between the cells 300 partially or entirely overlaps with the first area A1 of each of the solar cells 200 adjacent to each other. The bus electrode between the cells 300 connects the first solar cells G1 adjacent to each other in the second direction D2 of the arranged solar cells 200 with the second solar cells G2 adjacent to each other in the second direction and adjacent to the first solar cells G1 in the first direction D1 in series or in parallel.

In addition, the bus electrode in the cell 350 extends in the first direction D1 inside of each of the solar cells 200 adjacent to each other. The bus electrode in the cell 350 connects the solar cells 200 adjacent to each other in the first direction D1 of the arranged solar cells 200 in series or in parallel.

Accordingly, the solar cells 200 are connected in series or in parallel by the bus electrode between the cells 300 and the bus electrode in the cell 350 in the first direction D1. The solar cell module 1000 according to the present example embodiment includes the bus electrode between the cells 300 disposed along the sub electrode 233 in order to partially overlap with the solar cells 200 adjacent to each other in the first area A1 between the adjacent solar cells 200. A conductive paste may be disposed between the bus electrode between the cells 300 and the sub electrode 233a. Thus, the bus electrode between the cells 300 is electrically connected to the sub electrode 233a in the first area A1. In addition, the bus electrode between the cells 300 may be electrically connected to a portion of the finger electrode 232a connected to the sub electrode 233a. Therefore, the electrons or the holes may be captured from each of the finger electrode 232a and the sub electrode 233a of the adjacent solar cells 200, so that the efficiency of the solar cell 200 may be increased.

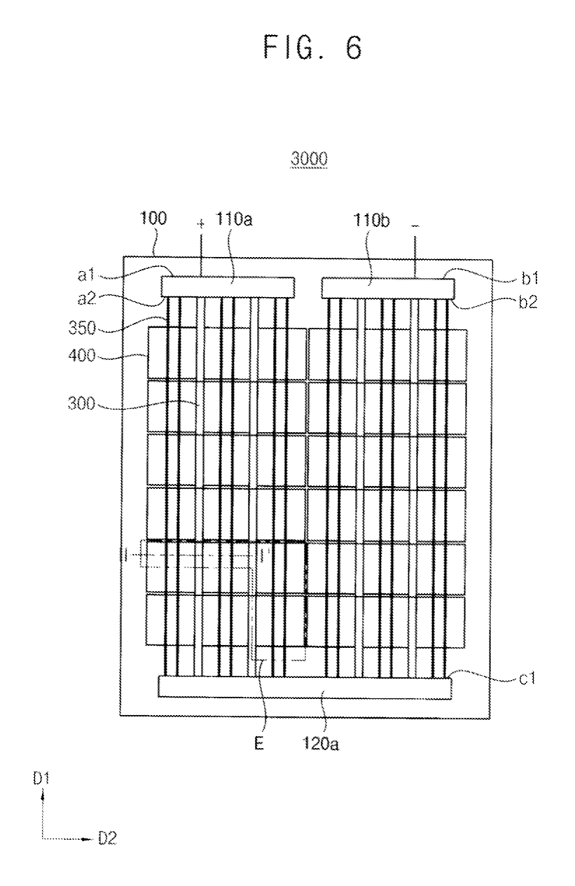

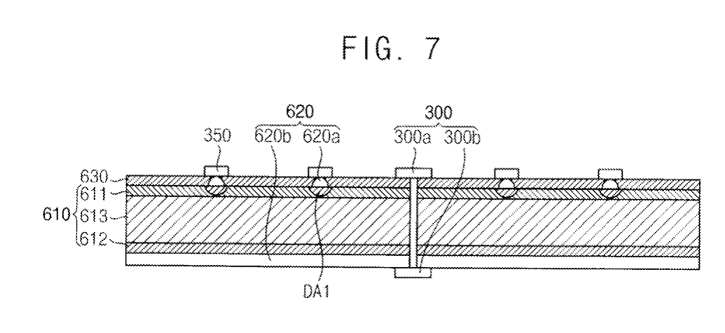

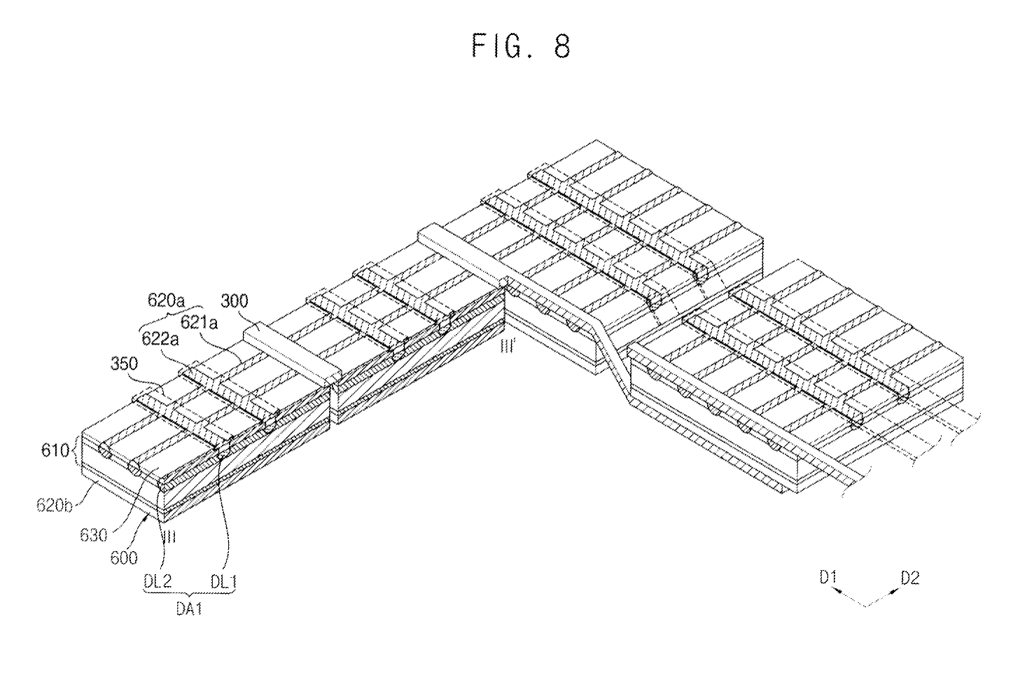

FIG. 6 is a plan view illustrating a solar cell module according to another example embodiment of the present invention. FIG. 7 is a cross-sectional view taken along II-II′ line of FIG. 6. FIG. 8 is a perspective view illustrating ‘B’ of FIG. 1.

Referring to FIG. 6, FIG. 7 and FIG. 8, a solar cell module 3000 according to the present example embodiment includes an array substrate 100, a solar cell 600 and a bus electrode between the cells 300. The solar cell module 3000 may further include a bus electrode in the cell 350, a first connection electrode 110a and 110b and a second connection electrode 120.

Since the array substrate 100 according to the present example embodiment is substantially the same as the array substrate according to the previous example embodiment illustrated in FIG. 1, any further explanation will be omitted.

The solar cell 600 includes a semiconductor substrate 610, a wire electrode 620 and a reflection blocking layer 630. The semiconductor substrate 610 includes a first doped area DA1, a first doped layer 611, a second doped layer 612 and a base layer 613. The wire electrode 620 and the reflection blocking layer 630 are formed on the semiconductor substrate 610.

The semiconductor substrate 610 may include a base layer 613 having a p-type semiconductor. The semiconductor substrate 610 includes a first surface receiving solar light and a second surface opposite to the first surface.

The first doped layer 611 may include an n-type semiconductor having a first dopant of a first concentration. The first doped layer 611 is formed on a first surface of the semiconductor substrate 610. A PN junction structure of the solar cell 600 may be defined according as the first doped layer 611 is formed on the semiconductor substrate 610. The first doped layer 611 substantially receives the solar light. The first doped layer 611 is entirely formed on the first surface except for the first doped area DA1. For example, when viewed in a plane, the first doped layer 611 may have a matrix shape divided by the first doped area DA1, and the first doped layer 611 may be arranged on the first surface. The first doped layer 611 collects electrons generated inside of the semiconductor.

The first doped area DA1 may include an (n+)-type semiconductor doped with the first dopant of a second concentration higher than the first concentration. The first doped area DA1 directly contacts the first wire electrode 620a formed on the first surface, so that a contact resistance between the first wire electrode 620a and the first doped layer 611 may be decreased. The first dopant may include an element in Group 13 including boron (B), aluminum (Al), etc., or an element in Group 15 including phosphorous (P), arsenic (As), etc. In the present example embodiment, the first dopant includes the element in Group 15.

The first doped area DA1 is formed corresponding to the first wire electrode 620a. Thus, the first doped area DA1 may include first doped lines DL1 and second doped lines DL2. The first doped liens DL1 are extended in a first direction D1 and are spaced apart from each other in the second direction D2. The second doped liens DL2 are extended in the second direction D2 and are spaced apart from each other in the first direction D1. The first doped lines DL1 cross the second doped lines DL2.

The first wire electrode 620a may include body electrodes 621a and finger electrodes 622a. The body electrodes 621a may be extended in the first direction D1 and arranged in the second direction D2. The finger electrodes 232 are extended from the body electrodes 231. The finger electrode 232 may be extended in the second direction D2 crossing the first direction D1 and arranged in the first direction D1.

The reflection blocking layer 630 is formed on the first doped layer 611. The reflection blocking layer 630 may minimize a reflection of the solar light incident to the first doped layer 611. In addition, the reflection blocking layer 630 may protect the semiconductor substrate 610. The reflection blocking layer 630 may include silicon nitride. The reflection blocking layer 630 may be formed in regions divided by crossing the body lines 621 adjacent to each other with the finger lines 622 adjacent to each other. When the first doped layer 611 is arranged in a matrix shape defined by the first doped area DA1, the reflection blocking layer 630 may be also arranged in a matrix shape when viewed in a plane. The reflection blocking layer 630 is disposed on substantially the same plane as the first wire electrode 620a so that the first wire electrode 620a directly makes contact with the first doped area DA1 and the reflection blocking layer 630 directly makes contact with the first doped layer 611.

The second doped layer 612 entirely covers a second surface of the semiconductor substrate 610. The second doped layer 612 includes a (p+)-type semiconductor. The second doped layer 612 collects holes generated inside of the semiconductor substrate 610.

The second wire electrode 620b is formed on the second doped layer 612. The second wire electrode 620b is opposite to the first wire electrode 620a. The second wire electrode 620b may include one of silver (Ag) and aluminum (Al).

Alternately, the semiconductor substrate may include the n-type semiconductor, the first doped layer 611 may include the p-type semiconductor, the first doped area DA1 may include the (p+)-type semiconductor, and the second doped layer 612 may include the (n+) type semiconductor.

The bus electrode between the cells 300 extends in the first direction D1 between adjacent solar cells 600 having the first wire electrode 620a and 620b (hereinafter, 620). The bus electrode between the cells 300 partially overlaps with the adjacent solar cells 600 to directly make contact with the reflection blocking layer 630 and the wire electrode 620 of each of the solar cells 600 adjacent to each other. For example, the bus electrode between the cells 300 partially overlaps with the finger electrode 622 extended in the second direction in each of the solar cells 600 adjacent to each other to be electrically connected to the finger electrode 622. Thus, the bus electrode between the cells 300 may output the electrons or the holes provided from the finger electrode 622 disposed in each of the solar cells 600 adjacent to each other.

The bus electrode between the cells 300 may connect first solar cells adjacent to each other in the second direction of the adjacent solar cells with second solar cells adjacent to each other in the second direction D2 and adjacent to the first solar cells in the first direction D1 in series or in parallel.

Since the bus electrode between the cells 300 which connects the first solar cells with the second solar cells in series or in parallel according to the present example embodiment is substantially the same as the bus electrode between the cells according to the previous example embodiment illustrated in FIG. 1, any further repetitive description will be omitted.

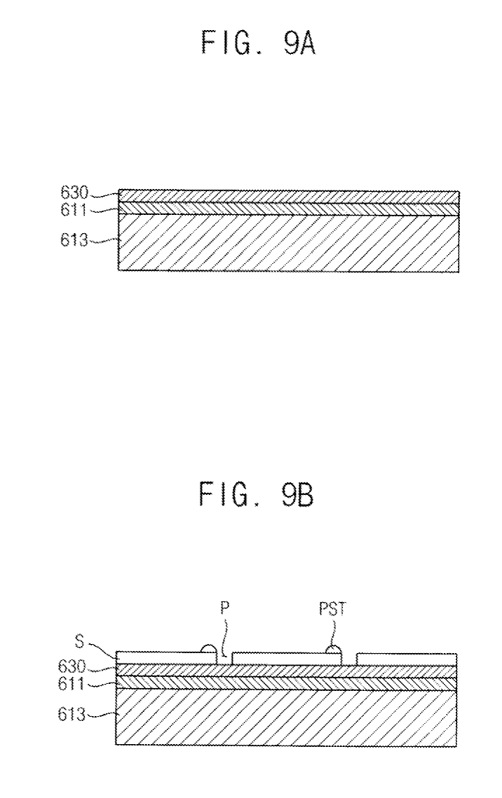

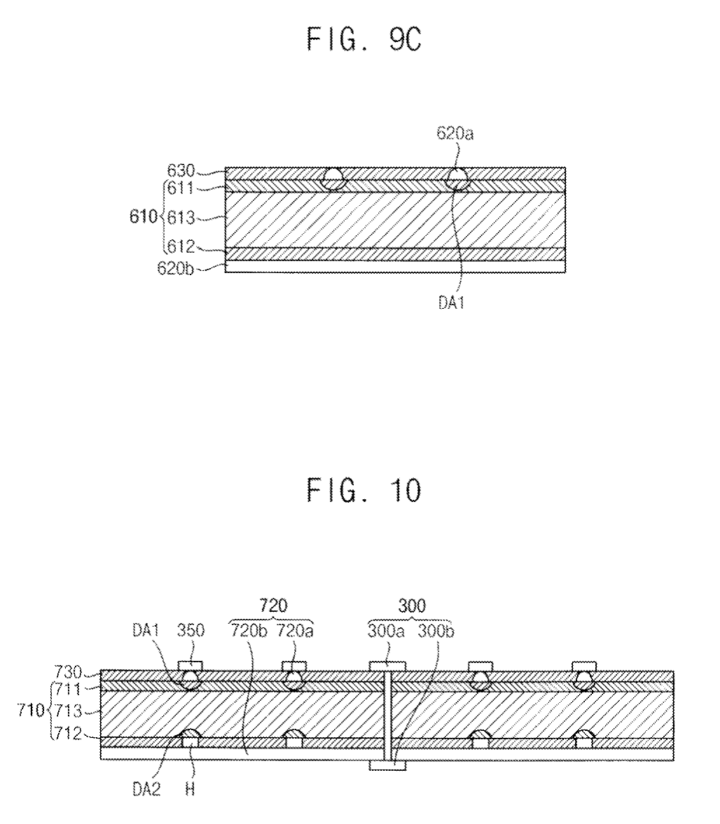

FIGS. 9A to 9C are cross-sectional views illustrating a method of manufacturing the solar cell module of FIG. 6.

Referring to FIG. 7 and FIG. 9A, the first doped layer 611 is formed on the first surface of the base substrate 613. The first doped layer 611 may be formed by doping the element in Group 15 into the base substrate 613 by a thermal diffusion method or an ion implantation method which is a conventional method for implanting impurities. The first doped layer 611 is less affected by a temperature not less than about 850° C. because the first doped layer 611 is formed on the base substrate 613 before forming components of the solar cell 600, although the first doped layer 611 may be formed by the thermal diffusion method or the ion implantation method.

Then, the reflection blocking layer 630 is formed on the first surface of the semiconductor substrate 610 having the first doped layer 611.

Referring to FIG. 7 and FIG. 9B, a stencil S is disposed over the first surface of the semiconductor substrate 610 having the reflection blocking layer 630 formed on the semiconductor substrate 610. The stencil S includes a wire electrode pattern P corresponding to the wire electrode 620. A wire electrode material PST is spread on the stencil S. The wire electrode material PST includes silver (Ag) and may be in a paste state. The wire electrode material PST is inserted into the wire electrode pattern P. Thus, using such a screen printing, the wire electrode material PST is disposed on the reflection blocking layer 630 to form the first wire electrode 620a.

In addition, the wire electrode material PST is directly coated on the second surface of the base substrate 613 to form the second wire electrode 620b.

Referring to FIG. 7 and FIG. 9C, the semiconductor substrate 610 having the first wire electrode 620a formed on the first surface and the second wire electrode 620b formed on the second surface is heated.

By heating the semiconductor substrate 610, a metal of the first wire electrode 620a is diffused into the semiconductor substrate 610. In addition, by heating the semiconductor substrate 610, a metal of the second wire electrode 620b is diffused into the semiconductor substrate 610. The first and second doped areas DA1 and DA2 are formed by the metal diffused into the semiconductor substrate 610.

Referring to FIG. 7 and FIG. 9D, a plurality of solar cells 600 are arranged on the array substrate (not shown). The bus electrode between the cells 300 extends in the first direction D1 between the solar cells 600 adjacent to each other in the second direction D2 of the arranged solar cells 600. Thus, the bus electrode between the cells 300 partially overlaps with each of the solar cells 600. The bus electrode between the cells 300 connects the first solar cells G1 adjacent to each other in the second direction D2 of the arranged solar cells with the second solar cells G2 adjacent to each other in the second direction and adjacent to the first solar cells G1 in the first direction D1 of the arranged solar cells in series or in parallel.

In addition, the bus electrode in the cell 350 extends in the first direction D1 in the arranged solar cells 600. The bus electrode in the cell 350 connects the solar cells 600 adjacent in the first direction D1 of the arranged solar cells in series or in parallel.

Therefore, the solar cells 600 are connected in the first direction D1 by the bus electrode between the cells 300 and the bus electrode in the cell 350 in series or in parallel. Thus, the solar cell module 3000 according to the present example embodiment illustrated in FIG. 6 may be manufactured.

The solar cell module 3000 according to the present example embodiment may output the electricity by the bus electrode between the cells 300, although the finger electrode 622a is opened when formed. Accordingly, the power efficiency of the solar cell module 3000 may be increased.

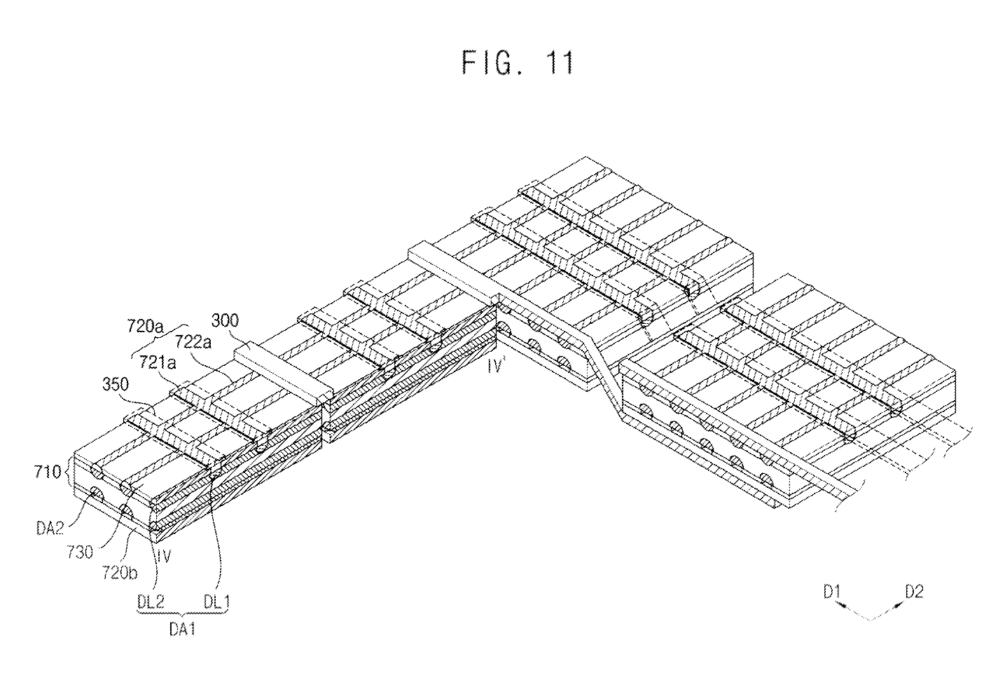

FIG. 10 is a cross-sectional view illustrating a solar cell module according to still another example embodiment of the present invention. FIG. 11 is a perspective view illustrating the solar cell module.

Referring to FIG. 10 and FIG. 11, a solar cell module 4000 according to the present example embodiment includes an array substrate (not shown), a solar cell 700 and a bus electrode between the cells 300. The solar cell module 4000 may further include a bus electrode in the cell 350, a first connection electrode (not shown) and a second connection electrode (not shown).

Since the array substrate, the first electrode and the second electrode according to the present example embodiment is substantially the same as the array substrate, the first electrode and the second electrode according to the previous example embodiment illustrated in FIG. 6, any further explanation will be omitted.

The solar cell 700 includes a semiconductor substrate 710, a first wire electrode 720a, a second wire electrode 720b, a first reflection blocking layer 730a and a second reflection blocking layer 730b. The semiconductor substrate 710 includes a first surface receiving solar light and having a first doped area DA1 and a first doped layer 711, and a second surface opposite to the first surface and having a second doped area DA2. The first wire electrode 720a, the second wire electrode 720b, the first reflection blocking layer 730a and the second blocking layer 730b are formed on the semiconductor substrate 710.

The semiconductor substrate 710 may include a base layer 713 having a p-type semiconductor or an n-type semiconductor.

Since the first doped area DA1, the first doped layer 711, the first wire electrode 720a and the first reflection blocking layer 730a formed on the first surface of the semiconductor substrate 710 and the second wire electrode 720b formed on the second surface of the semiconductor substrate 710 according to the present example embodiment is substantially the same as the first doped area, the first doped layer, the first wire electrode, the second wire electrode and the reflection blocking layer according to the previous example embodiment illustrated in FIG. 6, any further explanation will be omitted.

The second doped area DA2 may include a (p+)-type semiconductor. The second doped area DA2 includes first doped dots. Each of the first doped dots may have a dot shape when viewed in a plane and may have a hemisphere shape when viewed in three dimensions. The first doped dots may be arranged to have a matrix shape in the first direction D1 and the second direction D2. The second doped area DP2 functions substantially the same as the second doped layer according to the previous example embodiment illustrated in FIG. 9. The second doped area DA2 includes the first doped dots so that the second wire electrode 720b may make contact with the second doped area DA2 at a required portion. Thus, the first doped dots may prevent the reliability of an electric connection between the second doped area DA2 and the second wire electrode 720b from being decreased due to crystal defects or sources of pollution.

The second reflection blocking layer 730b is formed on the second surface of the semiconductor substrate 710. The second reflection blocking layer 730b may include silicon nitride or silicon oxide. The second reflection blocking layer 730b includes holes H exposing each of the first doped dots. The first doped dots may directly make contact with the second wire electrode 720b through the holes H of the second reflection blocking 730b.

The bus electrode between the cells 300 extends in the first direction D1 between adjacent solar cells 700 having the wire electrode 720. The bus electrode between the cells 300 partially overlaps with the adjacent solar cells 700 to directly make contact with the first reflection blocking layer 730a, the first wire electrode 720a and the second wire electrode 720b of each of the solar cells 700 adjacent to each other. For example, the bus electrode between the cells 300 partially overlaps with the finger electrode 722 extending in the second direction D2 on the first surface of each of the solar cells adjacent to each other to be electrically connected to the finger electrode 722. In addition, the bus electrode between the cells 300 partially overlaps with the second wire electrode 720b on the second surface of each of the solar cell 700 adjacent to each other to be electrically connected to the second wire electrode 720b. Thus, the bus electrode between the cells 300 may output the electrons or the holes provided from the first and second wire electrodes 720a and 720b disposed in each of the solar cells 700 adjacent to each other.

The bus electrode between the cells 300 may connect first solar cells adjacent to each other in the second direction D2 of the adjacent solar cells with second solar cells adjacent to each other in the second direction D2 and adjacent to the first solar cells of the adjacent solar cells in series or in parallel.

Since the bus electrode between the cells 300 connecting the first solar cells with the second solar cells in series or in parallel according to the present example embodiment is substantially the same as the previous example embodiment illustrated in FIG. 1, any further explanation will be omitted.

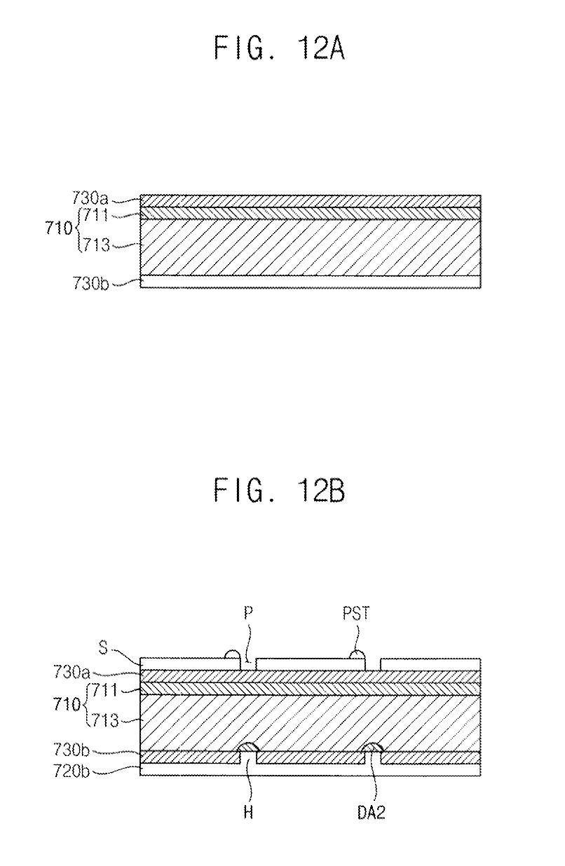

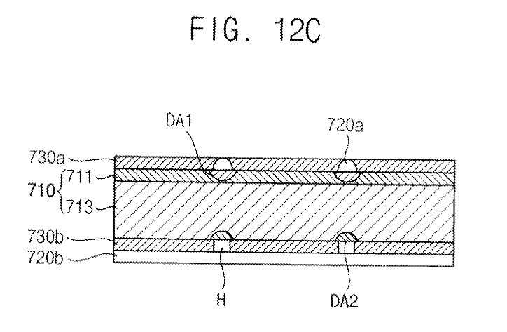

FIGS. 12A to 12C are cross-sectional views illustrating a method of manufacturing the solar cell module of FIG. 10.

Referring to FIG. 11 and FIG. 12A, the first doped layer 711 is formed in the base substrate 713. The first doped layer 711 may be formed by doping the element in Group 15 into the base substrate 713 by a thermal diffusion method or an ion implantation method which is a conventional method for implanting impurities. The first doped layer 711 is less affected by a temperature not less than about 850° C. because the first doped layer 711 is formed on the base substrate 713 before forming components of the solar cell 600, although the first doped layer 711 may be formed by the thermal diffusion method or the ion implantation method. The first reflection blocking layer 730a is formed on the first surface of the semiconductor substrate 710 having the first doped layer 711. The second reflection blocking layer 730b is formed on the second surface of the semiconductor substrate 710.

Referring to FIG. 11 and FIG. 12B, a stencil S is disposed over the first surface of the semiconductor substrate 710 having the reflection blocking layer 730a. The stencil S includes a wire electrode pattern P corresponding to the wire electrode 720. A wire electrode material PST is spread on the stencil S. The wire electrode material PST includes silver (Ag) and may be in a paste state. The wire electrode material PST is inserted into the wire electrode pattern P. Thus, by using such a screen printing, the wire electrode material PST is disposed on the first reflection blocking layer 730a to form the first wire electrode 720a.

Holes H having a dot shape are formed on the second surface of the semiconductor substrate 710 having the second reflection blocking layer 730b using a mask. Impurities are implanted into the holes H in the thermal diffusion method or an ion implantation method which is a conventional method, so that the second doped area DA2 is formed. The second doped area DA2 has a dot shape such as the holes H.

The wire electrode material PST is directly coated on the second surface of the semiconductor substrate 710 so that the second wire electrode 720b is formed.

Referring to the FIG. 11 and FIG. 12C, the semiconductor substrate 710 having the first wire electrode 720a formed on the first surface and the second wire electrode 720b formed on the second surface is heated.

By heating the semiconductor substrate 710, a metal of the first wire electrode 720a is diffused into the semiconductor substrate 710 so that the first doped area DA1 is formed.

The solar cell module 4000 according to the present example embodiment may output the electricity by the bus electrode between the cells 300, although the finger electrode 722a is opened when formed. Accordingly, the power efficiency of the solar cell module 4000 may be increased.

According to the present invention, the bus electrode between the cells is disposed between the adjacent solar cells to partially overlap with each of the solar cells adjacent to each other, thereby using the opened wire electrode. Accordingly, the present invention may improve the power efficiency.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A solar cell module comprising:
an array substrate;
a plurality of solar cells arranged adjacent to each other on the array substrate, each of the solar cells including a wire electrode; and
a bus electrode between the cells partially overlapping with each of the adjacent solar cells and extending in a first direction, to be electrically connected to the wire electrode of each of the adjacent solar cells.

2. The solar cell module of claim 1, wherein each of the solar cells comprises:
a semiconductor substrate including first and second surfaces, the first surface having a first area corresponding to an edge of the semiconductor substrate and a second area except for the first area of the semiconductor substrate, the second surface being opposite to the first surface and having the first and second areas; and
a transparent electrode formed in at least one second area of the first and second surfaces.

3. The solar cell module of claim 2, wherein the semiconductor substrate comprises:
a base substrate;
a first semiconductor layer formed on at least one of the first and second surfaces; and
a second semiconductor layer formed on the first semiconductor layer.

4. The solar cell module of claim 3, wherein the wire electrode is disposed in the first and second areas.

5. The solar cell module of claim 3, wherein the wire electrode comprises:
a plurality of body electrodes extending in the first direction; and
a plurality of finger electrodes including first and second end portions, the first end portion being disposed in the second area to be connected to the body electrode, the second end portion being disposed in the first area.

6. The solar cell module of claim 5, further comprising a bus electrode in the cell extending in the first direction and formed along each of the body electrodes, to be electrically connected to the wire electrode of the solar cell.

7. The solar cell module of claim 5, wherein the wire electrode further comprises a sub electrode extending in the first direction in the first area to electrically connect the second end portions of the finger electrodes disposed in the first area.

8. The solar cell module of claim 1, wherein the adjacent solar cells comprise first solar cells adjacent to each other in the second direction and second solar cells adjacent to the first solar cells in the first direction,
a first end portion of the bus electrode between the cells extends in the first direction between the first solar cells and partially overlaps with the first surface of each of the first solar cells, and
a second end portion of the bus electrode between the cells extends in the first direction between the second solar cells and partially overlaps with the second surface of each of the second solar cells.

9. The solar cell module of claim 1, wherein the adjacent solar cells comprise first solar cells adjacent to each other in the second direction and second solar cells adjacent to the first solar cells in the first direction,
a first end portion of the bus electrode between the cells extends in the first direction between the first solar cells and partially overlaps with the first surface of each of the first solar cells, and
a second end of the bus electrode between the cells extends in the first direction between the second solar cells and partially overlaps with the first surface of each of the second solar cells.

10. A method of manufacturing a solar cell module, the method comprising:
forming a plurality of solar cells having a wire electrode;
arranging the solar cells adjacent to each other on an array substrate; and
forming a bus electrode between the cells partially overlapping with each of adjacent solar cells and extending in a first direction, to be electrically connected to the wire electrode of each of the adjacent solar cells.

11. The method of claim 10, wherein the solar cells are formed by:
mounting a semiconductor substrate having a first surface and a second surface opposite to the first surface to a shield tray having a through-hole;
depositing a transparent electrode in a second area corresponding to the through-hole except for a first area corresponding to an edge of the semiconductor substrate on at least one of the first and second surfaces; and
forming the wire electrode on at least one of the first and second surfaces on which the transparent electrode is deposited.

12. The method of claim 11, wherein the wire electrode is formed by:
spreading a wire electrode paste in the first and second areas on the first surface; and
screen-printing the wire electrode having a plurality of body electrodes and a plurality of finger electrodes, the body electrodes extending in the first direction, the finger electrodes having first and second end portions, the first end portion being disposed in the second area to be connected the body electrodes, the second end portion being disposed in the first area.

13. The method of claim 12, further comprising:
forming a bus electrode in the cell extending in the first direction and corresponding to the body electrodes, to be electrically connected to the wire electrode of the solar cell.

14. The method of claim 11, wherein the wire electrode is formed by:
spreading a wire electrode paste in the first and second areas on the second surface; and
screen-printing the wire electrode.

15. The method of claim 10, wherein the bus electrode between the cells is formed by:
extending a first end portion of the bus electrode between the cells in the first direction between first solar cells adjacent to each other along the second direction, and adhering the first end portion to partially overlap with the first surface of each of the first solar cells adjacent to each other; and
extending a second end portion opposite to the first end portion in the first direction between second solar cells adjacent to the first solar cell along the first direction, and adhering the second end portion to partially overlap with the second surface of each of the second solar cells adjacent to each other.

16. The method of claim 10, wherein the bus electrode between the cells is formed by:
extending a first end portion of the bus electrode between the cells in the first direction between first solar cells adjacent to each other along the second direction, and adhering the first end portion to partially overlap with the first surface of each of the first solar cells adjacent to each other; and
extending a second end portion opposite to the first end portion in the first direction between second solar cells adjacent to the first solar cells along the first direction, and adhering the second end portion to partially overlap with the first surface of each of the second solar cells adjacent to each other.
